(19) United States
(12) Patent Application Publication
(10) Pub. No.: US 2007/0164297 A1
(43) Pub. Date: Jul. 19, 2007

(54) Optical-element integrated semiconductor integrated circuit and fabrication method thereof

(76) Inventors: Mikio Oda, Tokyo (JP); Hisaya Takahashi, Tokyo (JP); Kaichiro Nakano, Tokyo (JP); Hikaru Kouta, Tokyo (JP); Kohroh Kobayashi, Tokyo (JP)

Correspondence Address: SCULLY SCOTT MURPHY & PRESSER, PC, 400 GARDEN CITY PLAZA, SUITE 300, GARDEN CITY, NY, 11530, US

(21) Appl. No.: 10/584,735

(22) PCT Filed: Oct. 14, 2004
(86) PCT No.: PCT/JP04/15155

§ 371 Date: Jun. 26, 2006

(30) Foreign Application Priority Data
Dec. 26, 2003 (JP) 2003-434029

(51) Int. Cl. H01L 33/00; H01L 31/12; H01L 29/207; H01L 27/15; H01L 29/26

(52) U.S. Cl. 257/93; 257/79

(57) ABSTRACT

Light-emitting device array 2 is mounted on LSI 1, following which necessary light-emitting devices 2a among two or more light-emitting devices 2 that make up mounted light-emitting device array 2 are allowed to remain and unnecessary light-emitting devices 2a are removed in order to mount light-emitting devices on a plurality of output ports that are randomly arranged on LSI 1.

### TECHNICAL FIELD

The present invention relates to a semiconductor integrated circuit (hereinbelow also referred to as an “LSI”) and to a method of fabricating the semiconductor integrated circuit.

### BACKGROUND ART

Although the processing speed of LSI is advancing toward ever-higher levels, there is a limit to the transmission capabilities of electrical wiring between a plurality of LSI, and attention has therefore focused on transmission that employs optical signals, which is not only capable of high-speed transmission and long-distance transmission but also features superior resistance to electromagnetic noise. It is believed that if an electrical signal that is supplied as output from a particular LSI is converted to an optical signal for transmission by an optical line and then reconverted to an electrical signal before input to another LSI, higher transmission speed can be realized than when using an electrical signal alone.

JP-A-2001-036197 discloses an optoelectronic-integrated element in which optical elements and an LSI connected by electrical wiring are integrated within the same package. In this optoelectronic integrated element, an electronic integrated element bare chip is secured on a base plate, and optical elements are secured in proximity to this bare chip with an interconnect means interposed. In this case, the optical elements are a surface-emission laser array or a photodetector array and are directly mounted on inner leads or on the electronic integrated element. The input/output ports of the electronic integrated element are each arranged around the periphery of the electronic integrated element with the photodetector array mounted to correspond to the input ports and the surface emission lasers mounted to correspond to the output ports. More specifically, in a form in which the optical elements are directly mounted on the electronic integrated element, the pads of the optical elements are electrically connected to the input/output ports of the electronic integrated element that are arranged to correspond with the arrangement of these pads. Alternatively, in the form in which the electronic integrated element and optical element are electrically connected by inner leads, the pads on which the electronic integrated element is mounted and the pads on which the optical element array is mounted (which are arranged to match the pad arrangement of the optical element array in order to mount the optical element array) are electrically connected through the use of inner leads that have a one-to-one correspondence with the pads.

JP-A-2000-332301 discloses a semiconductor device in which a photodetector array is arranged to correspond to a plurality of input ports that are arranged at the periphery of an LSI, and a light-emitting device array is arranged to correspond to a plurality of output ports. In addition, JP-A-2000-332301 describes as its object a solution to the problem of increase in the size of parts for converting the LSI input/output to light when an LSI, light-emitting devices, and photodetectors are separately mounted in rows on a substrate. JP-A-2000-332301 further describes directly mounting the photodetector array and light-emitting device array to a LSI chip to enable a more compact part for converting the input/output of the LSI to light.

However, the prior art described in the aforementioned publications is technology that presupposes the arrangement of the input/output ports of the LSI aligned in a fixed direction on the periphery of the LSI. Accordingly, where there is a plurality of input/output ports of the LSI, and moreover, when these input/output ports are randomly (irregularly) arranged, the photodetector and light-emitting devise of one channel must be prepared in exactly the number required, and these elements must be mounted one at a time to match the positions of the input/output ports of the LSI. However, mounting a plurality of optical elements one at a time results in disparity in the heights of the photoreceptor surface and in light-emitting surface of each optical element and increased loss in optical coupling with external devices. In addition, the mounting of optical elements becomes time-consuming and is prone to high costs.

### DISCLOSURE OF THE INVENTION

It is an object of the present invention to provide an optical-element integrated semiconductor integrated circuit and a fabrication method for the semiconductor integrated circuit in which photodetectors are provided at each of randomly arranged LSI input ports, light-emitting devices are similarly provided at each of randomly arranged LSI output ports, and the heights of the photoreception surfaces and light-emitting surfaces of these photodetectors and light-emitting devices are uniform.

As an optical-element integrated LSI of the present invention that achieves at least one of these objects, two or more optical elements for converting electrical signals that are the input to and output from a semiconductor integrated circuit to optical signals are mounted on a semiconductor integrated circuit, and the heights of these two or more optical elements are identical. In this case, the two or more optical elements can be: light-emitting devices for converting electrical signals that are supplied from an electrical signal output port of the semiconductor integrated circuit to optical signals for output to an outside component; photodetectors for converting optical signals received as input from the outside to electrical signals for supplying to the electrical signal input ports of the semiconductor integrated circuit; or a combination of these light-emitting devices and photodetectors. In this case, “heights of the light-emitting devices” refers to the distance from the surface (mounting surface) of the semiconductor integrated circuit on which the light-emitting devices are mounted to the light-emitting surfaces of the light-emitting devices. Further, “the heights of the photodetectors are identical” means that the distances from the surface (mounting surface) of the semiconductor integrated circuit on which the photodetectors are mounted to the photoreception surfaces of the photodetectors are identical.

When the two or more optical elements described above are a combination of light-emitting devices and photodetectors, the heights of the two or more light-emitting devices and the heights of the two or more photodetectors can each be made uniform, and the heights of the light-emitting devices and the photodetectors can be made different. Of course, the heights of all of the light-emitting devices and photodetectors can be made uniform, or the heights of a portion of the light-emitting devices and photodetectors can be made uniform.

The two or more optical elements mounted on a semiconductor integrated circuit can be divided into two or more groups and the heights of the optical elements belonging to each group can be made uniform, and the heights of optical elements belonging to different groups can be made different. In this case as well, the two or more optical elements can be the above-described light-emitting devices or photodetectors or a combination of light-emitting devices and photodetectors.

In addition, an optics element (such as a lens) having the capability to focus incident light can be provided in the two or more optical elements that are mounted on the semiconductor integrated circuit.

Further, all or a portion of the two or more optical elements that are mounted on the semiconductor integrated circuit can be electrically continuous, or conversely, each of the optical elements can be electrically isolated.

Still further, when solder is used to secure two or more optical elements to the semiconductor integrated circuit, solder having two or more different melting points can be used selectively. In this case, the solder having different melting points can be selected and used according to the type of optical element that is mounted or according to the above-described groups.

One fabrication method of an optical-element integrated LSI according to the present invention that can achieve at least one of the above-described objects includes optical element mounting steps of: forming bumps on necessary optical elements of the optical element array composed of two or more optical elements formed on an element substrate; using these bumps to mount the optical element array on the semiconductor integrated circuit to connect necessary optical elements to the semiconductor integrated circuit; covering necessary optical elements that have been connected to the semiconductor integrated circuit with a protective film; removing unnecessary optical elements that are not covered by the protective film from the optical element array; and removing the protective film.

Another fabrication method of an optical-element integrated LSI of the present invention includes optical element mounting steps of: covering with a protective film necessary optical elements of an optical element array composed of two or more optical elements formed on an element substrate; removing functional portions of unnecessary optical elements that are not covered with a protective film; removing the protective film; and mounting on a semiconductor integrated circuit the optical element array from which the functional portions of unnecessary optical elements have been removed and connecting necessary optical elements to the semiconductor integrated circuit.

According to another fabrication method of the optical-element integrated LSI of the present invention, light-emitting devices are mounted by either one of the above-described two types of optical element mounting steps, and photodetectors are mounted by the other method.

The fabrication method of the optical-element integrated LSI of the present invention can also include a step of etching the element substrate to produce a thin film and a step of etching the element substrate to form a lens.

By means of the optical-element integrated LSI and the fabrication method of the LSI described in the foregoing explanation, the following effects can be obtained. Specifically, even when there is a plurality of input/output ports on an LSI and these input/output ports are further arranged irregularly at various positions, an optical-element integrated LSI can be provided in which photodetectors are mounted at the same height on each input port and light-emitting devices are mounted at the same height on each output port. By optically coupling with a plurality of optical circuits such as optical fiber and optical waveguides, this optical-element integrated LSI can realize high-speed, long-distance transmission that further features excellent resistance to noise. By matching the heights of coupling portions of optical circuits that the photodetectors are to optically join under the above-described conditions of use, the present invention can further obtain the effect of realizing highly efficient optical coupling for all channels of the optical elements. Still further, because the realization of highly efficient optical coupling on all channels enables effective use of the strength of optical signals, the present invention can further obtain the effect of further increasing the distance over which transmission can be realized. Alternatively, even when optical transmission is over short distances, the highly efficient optical coupling enables transmission of optical signals at higher strength, whereby the present invention can obtain the effect of improving resistance to noise.

In addition, because a plurality of optical elements are collectively mounted in batches, a decrease in the number of fabrication steps and a consequent decrease in cost can be anticipated compared to a case of successively mounting a plurality of optical elements one at a time. This effect becomes more conspicuous as the number of mounted optical elements increases.

### BRIEF DESCRIPTION OF THE DRAWINGS

FIG. 1A is a schematic plan view showing an example of an optical-element integrated LSI according to the present invention;

FIG. 1B is a schematic sectional view of an example of an optical-element integrated LSI according to the present invention;

FIG. 2A is a schematic view showing one fabrication step of the optical-element integrated LSI shown in FIG. 1A;

FIG. 2B is a schematic view showing the step that follows the fabrication step shown in FIG. 2A;

FIG. 2C is a schematic view showing the step that follows the fabrication step shown in FIG. 2B;

FIG. 2D is a schematic view showing the step that follows the fabrication step shown in FIG. 2C;

FIG. 3A is a schematic plan view showing another example of an optical-element integrated LSI according to the present invention;

FIG. 3B is a schematic sectional view showing another example of the optical-element integrated LSI according to the present invention;

FIG. 4A is a schematic view showing one fabrication step of the optical-element integrated LSI shown in FIG. 3A;

FIG. 4B is a schematic view showing the step that follows the fabrication step shown in FIG. 4A;

FIG. 4C is a schematic view showing the step that follows the fabrication step shown in FIG. 4B;

FIG. 4D is a schematic view showing the step that follows the fabrication step shown in FIG. 4C;

FIG. 4E is a schematic view showing the step that follows the fabrication step shown in FIG. 4D;

FIG. 5A is a schematic plan view showing another example of an optical-element integrated LSI according to the present invention;

FIG. 5B is a schematic sectional view showing another example of an optical-element integrated LSI according to the present invention;

FIG. 5C is a schematic sectional view showing a modification of the optical-element integrated LSI shown in FIG. 5B;

FIG. 6A is a schematic view showing one fabrication step of the optical-element integrated LSI shown in FIG. 5B;

FIG. 6B is a schematic view showing the step that follows the fabrication step shown in FIG. 6A;

FIG. 6C is a schematic view showing the step that follows the fabrication step shown in FIG. 6B;

FIG. 6D is a schematic view showing the step that follows the fabrication step shown in FIG. 6C;

FIG. 6E is a schematic view showing the step that follows the fabrication step shown in FIG. 6D;

FIG. 6F is a schematic view showing the step that follows the fabrication step shown in FIG. 6E;

FIG. 6G is a schematic view showing the step that follows the fabrication step shown in FIG. 6F;

FIG. 6H is a schematic view showing the step that follows the fabrication step shown in FIG. 6G;

FIG. 6I is a schematic view showing the step that follows the fabrication step shown in FIG. 6H;

FIG. 7A is a schematic view showing one step of another fabrication method of the optical-element integrated LSI shown in FIG. 5B;

FIG. 7B is a schematic view showing the step that follows the fabrication step shown in FIG. 7A;

FIG. 7C is a schematic view showing the step that follows the fabrication step shown in FIG. 7B;

FIG. 7D is a schematic view showing the step that follows the fabrication step shown in FIG. 7C;

FIG. 7E is a schematic view showing the step that follows the fabrication step shown in FIG. 7D;

FIG. 7F is a schematic view showing the step that follows the fabrication step shown in FIG. 7E;

FIG. 7G is a schematic view showing the step that follows the fabrication step shown in FIG. 7F;

FIG. 7H is a schematic view showing the step that follows the fabrication step shown in FIG. 7G;

FIG. 7I is a schematic view showing the step that follows the fabrication step shown in FIG. 7H;

FIG. 8A is a schematic view showing a step that substitutes for the fabrication step shown in FIG. 6G;

FIG. 8B is a schematic view showing a step that substitutes for the fabrication step shown in FIG. 6H;

FIG. 8C is a schematic view showing a step that substitutes for the fabrication step shown in FIG. 6I;

FIG. 9 is a schematic plan view showing an example of the relation between the designed mounting position and the actual mounting position of an optical element;

FIG. 10A is a schematic plan view showing another example of an optical-element integrated LSI according to the present invention;

FIG. 10B is a schematic plan view showing another example of an optical-element integrated LSI of the present invention;

FIG. 10C is a schematic enlarged sectional view showing an example of an optical element;

FIG. 10D is a schematic enlarged sectional view showing another example of an optical element;

FIG. 11A is a schematic sectional view showing another example of an optical-element integrated LSI of the present invention;

FIG. 11B is a schematic sectional view showing another example of an optical-element integrated LSI of the present invention;

FIG. 12 is a schematic sectional view showing another example of an optical-element integrated LSI of the present invention;

FIG. 13A is a schematic sectional view showing another example of an optical-element integrated LSI of the present invention;

FIG. 13B is a schematic sectional view showing a portion of the fabrication steps of the LSI shown in FIG. 13A;

FIG. 14A is a schematic plan view showing another example of an optical-element integrated LSI of the present invention;

FIG. 14B is a schematic sectional view showing another example of an optical-element integrated LSI of the present invention;

FIG. 15A is a schematic view showing one fabrication step of the optical-element integrated LSI shown in FIG. 14A and FIG. 14B;

FIG. 15B is a schematic view showing the step that follows the fabrication step shown in FIG. 15A;

FIG. 15C is a schematic view showing the step that follows the fabrication step shown in FIG. 15B;

FIG. 15D is a schematic view showing the step that follows the fabrication step shown in FIG. 15C;

FIG. 15E is a schematic view showing the step that follows the fabrication step shown in FIG. 15D;

FIG. 15F is a schematic view showing the step that follows the fabrication step shown in FIG. 15E;

FIG. 15G is a schematic view showing the step that follows the fabrication step shown in FIG. 15F;

FIG. 15H is a schematic view showing the step that follows the fabrication step shown in FIG. 15G;

FIG. 15I is a schematic view showing the step that follows the fabrication step shown in FIG. 15H;

FIG. 15J is a schematic view showing the step that follows the fabrication step shown in FIG. 15I;

FIG. 15K is a schematic view showing the step that follows the fabrication step shown in FIG. 15J;

FIG. 15L is a schematic view showing the step that follows the fabrication step shown in FIG. 15K;

FIG. 16A is a schematic plan view showing another example of an optical-element integrated LSI of the present invention;

FIG. 16B is a schematic sectional view showing another example of the optical-element integrated LSI of the present invention;

FIG. 17A is a schematic plan view showing an example of an optical-element integrated LSI fabricated by a fabrication method of the prior art;

FIG. 17B is a schematic sectional view showing an example of an optical-element integrated LSI fabricated by a fabrication method of the prior art;

FIG. 18A is a schematic plan view showing an example of an optical-element integrated LSI fabricated by the fabrication method of the present invention;

FIG. 18B is a schematic sectional view showing an example of an optical-element integrated LSI fabricated by the fabrication method of the present invention;

FIG. 19A is a schematic sectional view of an optoelectronic hybrid substrate on which the optical-element integrated LSI of the present invention is mounted; and

FIG. 19B is a schematic sectional view of an optoelectronic hybrid substrate on which the optical-element integrated LSI of the prior art is mounted.

### BEST MODE FOR CARRYING OUT THE INVENTION

### First Embodiment

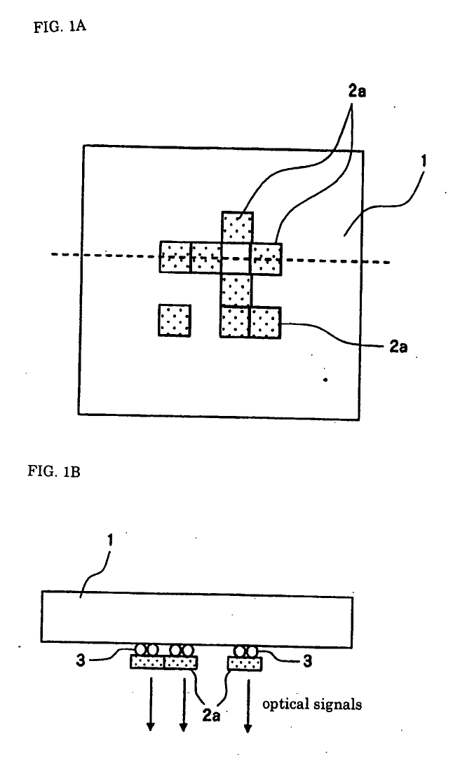

Explanation next regards the details of an example of an optical element integrated semiconductor integrated circuit (hereinbelow referred to as “optical-element integrated LSI”) of the present invention with reference to the figures. FIG. 1A is a schematic plan view showing the basic configuration of the optical-element integrated LSI of the present example, and FIG. 1B is a schematic sectional view. In the optical-element integrated LSI of this example, light-emitting device 2a is electrically connected by solder bumps 3 to electrical signal output ports (not shown) of LSI 1. There is a plurality of electrical signal output ports, and these electrical signal output ports are randomly arranged at various positions. In addition, light-emitting devices 2a are mounted at each electrical signal output port. Devices are used for light-emitting devices 2a that are capable of supplying light toward the rear-surface side (the downward side in FIG. 1B) of LSI 1. Accordingly, when an ON/OFF electrical signal is supplied from an electrical signal output port, this electrical signal is applied as input to light-emitting device 2a for conversion to an optical signal and supplied in a downward direction as an ON/OFF optical signal.

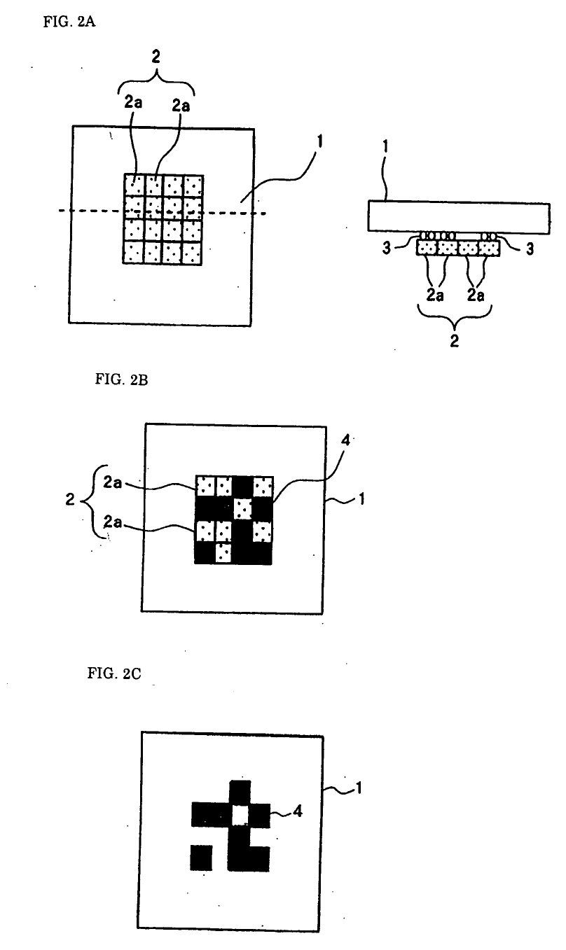

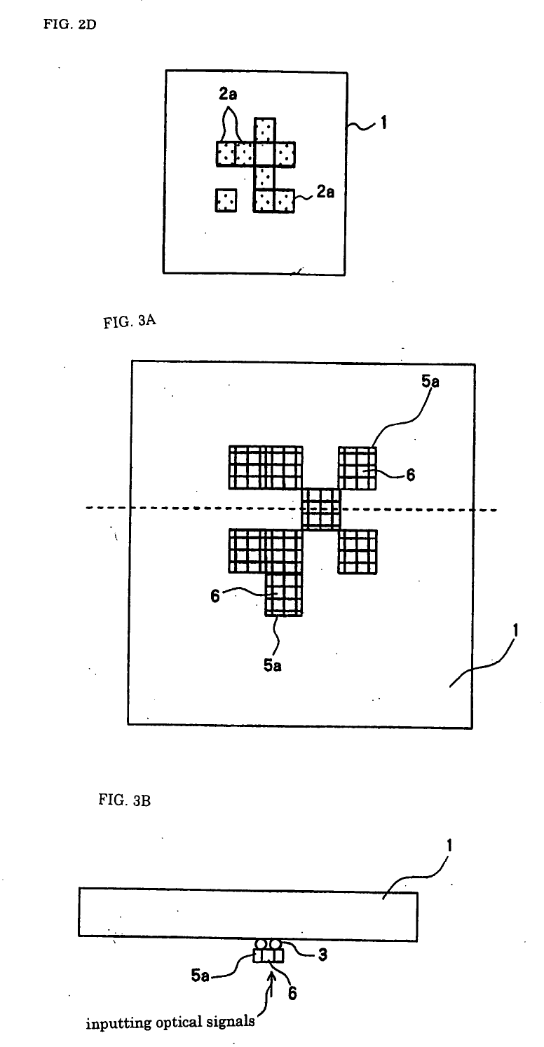

FIGS. 2A-2D show a fabrication method of the optical-element integrated LSI shown in FIGS. 1A and 1B. Although this explanation regarding the fabrication method takes as an example LSI 1 having eight electrical signal output ports, the number of light-emitting devices can be increased or decreased as appropriate when the number of electrical signal output ports is different.

As shown in FIG. 2A, light-emitting device array 2 is prepared in which light-emitting devices 2a are arranged in four rows and four columns on element substrate. Solder bumps 3 are formed on pads of necessary light-emitting devices 2a of the plurality of light-emitting devices 2a that make up light-emitting device array 2, and these solder bumps 3 that have been formed are used to electrically connect light-emitting device array 2 to LSI 1. In this case, “necessary light-emitting devices 2a” means light-emitting devices 2a that are to be mounted on electrical signal output ports of LSI 1. Accordingly, light-emitting devices 2a that are not to be mounted on electrical signal output ports of LSI 1 are placed on LSI 1 but are not electrically connected to LSI 1.

Next, as shown in FIG. 2B, protective film 4 is formed so as to cover only necessary light-emitting devices 2a of light-emitting devices 2a of the light-emitting device array 2. In this case, protective film 4 is formed by, for example, patterning by exposing and developing a resist.

As shown in FIG. 2C, unnecessary light-emitting devices 2a are next removed by etching, following which protective film 4 is removed as shown in FIG. 2D.

By means of the foregoing steps, an optical-element integrated LSI is fabricated in which light-emitting devices 2a are mounted on each of a plurality of electrical signal output ports that are arranged in any of the positions of LSI 1. In the fabrication method of this example, light-emitting device array 2 having a plurality of light-emitting devices 2a is mounted on LSI 1, following which unnecessary light-emitting devices 2a are removed while leaving necessary light-emitting devices 2a; whereby, light-emitting devices 2a can be mounted as a group on all electrical signal output ports despite the random arrangement of the plurality of electrical signal output ports of LSI 1. The step of mounting light-emitting devices 2a is thus simplified, and this simplification contributes to lower costs. In addition, because the heights of the light-emitting surfaces of the plurality of light-emitting devices 2a that makes up light-emitting device array 2 is aligned in advance, the light-emitting surfaces of light-emitting devices 2a that have been mounted on each electrical signal output port of LSI 1 are all the same height. When an optical-element integrated LSI is optically coupled with optical circuits and optical signals then transmitted to and received from, for example, an outside LSI or memory, the optical signal incident surface of each optical circuit is normally matched to a fixed height. Thus, uniformity in the heights of a plurality of light-emitting devices 2a that are mounted on LSI 1 means that the spacing between each light-emitting device 2a and the plurality of optical circuits with which it is optically coupled can be kept uniform on all channels and that highly efficient optical coupling can be realized between all light-emitting devices 2a and all optical circuits. In addition, the realization of highly efficient optical coupling means that the greater portion of light emitted from each light-emitting device 2a can be directed to the optical circuits, thereby obtaining the effects of enabling transmission of optical signals over longer distances, or, when transmitting over shorter distances, enabling transmission with greater noise resistance. Although the foregoing explanation regards one fabrication method, the optical-element integrated LSI of the present invention can be fabricated using other fabrication methods described hereinbelow, in which case the above-described actions and effects can be similarly obtained.

### Second Embodiment

Explanation next regards the details of another example of an optical-element integrated LSI of the present invention with reference to the figures. FIG. 3 is a schematic plan view showing the general configuration of the optical-element integrated LSI of the present embodiment, and FIG. 3B is a schematic sectional view. In the optical-element integrated LSI of the present embodiment, photodetectors 5a are electrically connected by solder bumps 3 to electrical signal input ports (not shown) of LSI 1. There is a plurality of the above-described electrical signal input ports, and these electrical signal input ports are randomly arranged at various positions. In addition, photodetectors 5a are mounted on respective electrical signal input ports. Devices that can receive light that is incident from the rear surface (the lower side in FIG. 3B) of LSI 1 are used for photodetectors 5a. Accordingly, when ON/OFF optical signals are received as input from the outside, these optical signals are converted to electrical signals by photodetectors 5a and supplied to electrical signal input ports as ON/OFF electrical signals.

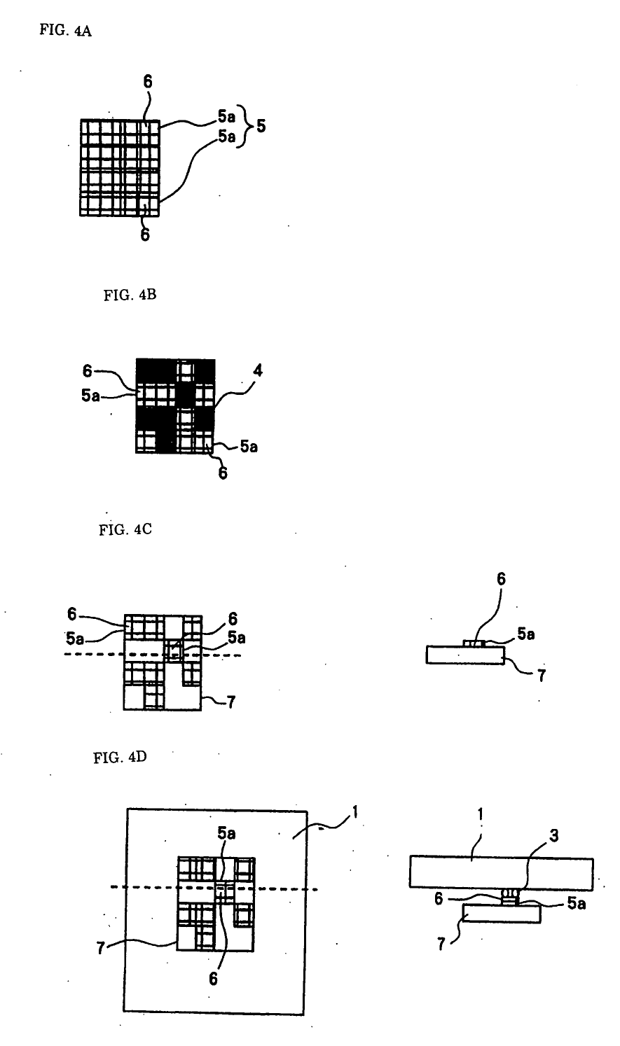

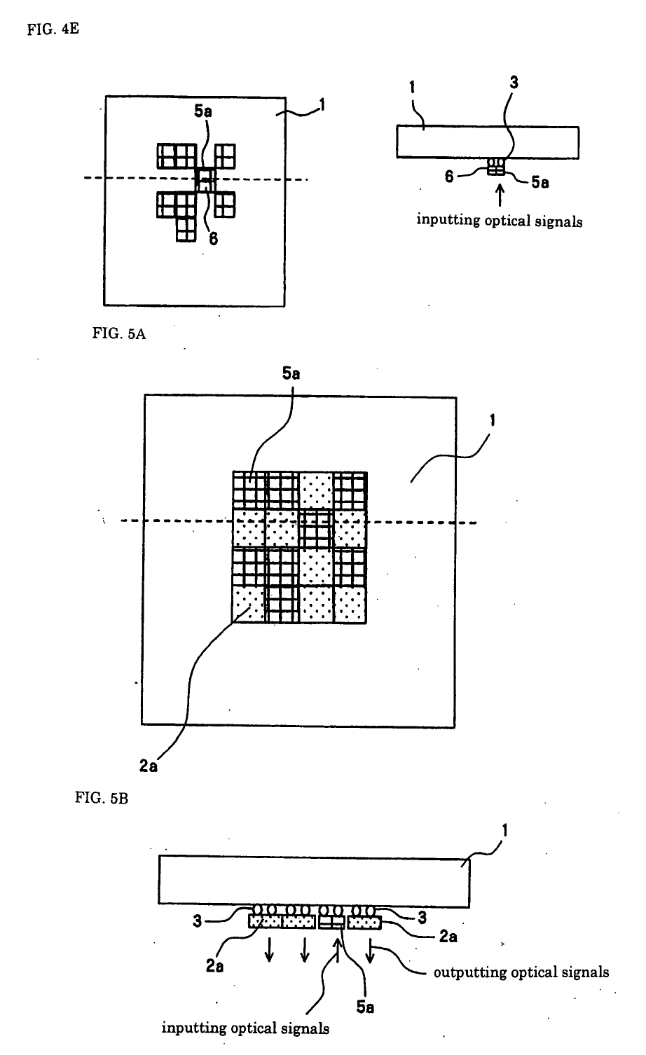

FIGS. 4A-4E show a fabrication method of the optical-element integrated LSI shown in FIGS. 3A and 3B. Although this explanation regarding a fabrication method takes as an example LSI 1 having eight electrical signal input ports, the number of photodetectors can be increased or decreased as appropriate when the number of electrical signal input ports is different.

First, as shown in FIG. 4A, photodetector array 5 is prepared in which photodetectors 5a are arranged in four rows and four columns on element substrate 7. Next, as shown in FIG. 4B, protective film 4 is formed to cover only necessary photodetectors 5a among the plurality of photodetectors 5a that make up photodetector array 5. In the present embodiment, protective film 4 is formed by patterning realized by, for example, exposing and developing a resist. In this case, “necessary photodetectors 5a” means photodetectors 5a that are later to be mounted on electrical signal input ports of LSI 1.

Next, as shown in FIG. 4C, unnecessary photodetectors 5a are removed by etching. However, in this etching process, etching is applied only to the functional portions (portions that are necessary for carrying out functions for receiving optical signals, and for converting the received optical signals to electrical signals to supply as output) 6 that are on the surface of unnecessary photodetectors 5a, and element substrate 7 is not etched. This provision is to allow use of element substrate 7 as a support for the entire plurality of photodetectors 5a.

Protective film 4 is next removed to obtain photodetector array 5 in which only necessary photodetectors 5a have functional portions 6. As shown in FIG. 4D, solder bumps 3 are next formed on the pads of each of photodetectors 5a having functional portions 6, and solder bumps 3 that are formed are then used to electrically connect necessary photodetectors 5a to LSI 1.

By means of the above-described steps, an optical-element integrated LSI is fabricated in which photodetectors 5a are mounted to each of a plurality of electrical signal input ports that are arranged at any of the positions of LSI 1. In the fabrication method of this embodiment, photodetector array 5, in which functional portions 6 of unnecessary photodetectors 5a have been removed in advance, is mounted on LSI 1, following which necessary photodetectors 5a and electrical signal input ports of LSI 1 are electrically connected. As a result, photodetectors 5a can be mounted as a group on all electrical signal input ports despite the random arrangement of a plurality of electrical signal input ports of LSI 1. As a result, the steps for mounting photodetectors 5a can be simplified, and this simplification contributes to lower costs. Further, the heights of the photoreception surfaces of the plurality of photodetectors 5a that make up photodetector array 5 are aligned in advance, and the photoreception surfaces of the plurality of photodetectors 5a that are mounted on respective electrical signal input ports of LSI 1 are therefore all the same height. In this case, when an optical-element integrated LSI is optically coupled to optical circuits and optical signals are transmitted to and received from, for example, an outside LSI or memory, the optical signal emergence surfaces of each optical circuit are normally aligned to a uniform height. The uniformity of the heights of the plurality of photodetectors 5a that are mounted on LSI 1 means that the spacing between each of photodetectors 5a and the plurality of optical circuits with which photodetectors 5a are optically coupled can be kept uniform on all channels, and that highly efficient optical coupling can be realized between all photodetectors 5a and all optical circuits. Further, the realization of highly efficient optical coupling means that the greater portion of emergent light from each optical circuit is received by each of photodetectors 5a, whereby photodetection is possible even in the case of a weak optical signal that was difficult or impossible to receive in the prior art. For example, photodetection is enabled even for weak optical signals that have been attenuated by long-distance transmission. Alternatively, the ability to receive the greater portion of relatively strong optical signals by photodetectors 5a enables transmission that is highly resistant to noise. The latter effect is particularly conspicuous when transmitting over short distances.

### Third Embodiment

Explanation next regards the details of another example of an optical-element integrated LSI of the present invention with reference to the figures. FIG. 5A is a schematic plan view showing the general configuration of the optical-element integrated LSI of the present embodiment, and FIG. 5B shows a schematic sectional view. In the optical-element integrated LSI of the present embodiment, light-emitting devices 2a are electrically connected by solder bumps 3 to electrical signal output ports (not shown) of LSI 1, and photodetectors 5a are electrically connected by solder bumps 3 to electrical signal input ports (not shown). LSI 1 has a plurality of electrical signal output ports and electrical signal input ports, and these ports are randomly arranged at various positions.

Devices capable of supplying light toward the rear-surface side (the downward side in FIG. 5B) of LSI 1 are used for light-emitting devices 2a. Thus, when an ON/OFF electrical signal is supplied as output from an electrical signal output port, this electrical signal is applied as input to light-emitting device 2a to be converted to an optical signal, and is downwardly supplied as an ON/OFF optical signal. On the other hand, devices capable of receiving light that is incident from the rear-side surface (the downward side in FIG. 5B) of LSI 1 are used for photodetectors 5a. Thus, when an ON/OFF optical signal is applied as input from the outside, this optical signal is converted to an electrical signal by photodetector 5a and supplied to an electrical signal input port as an ON/OFF electrical signal.

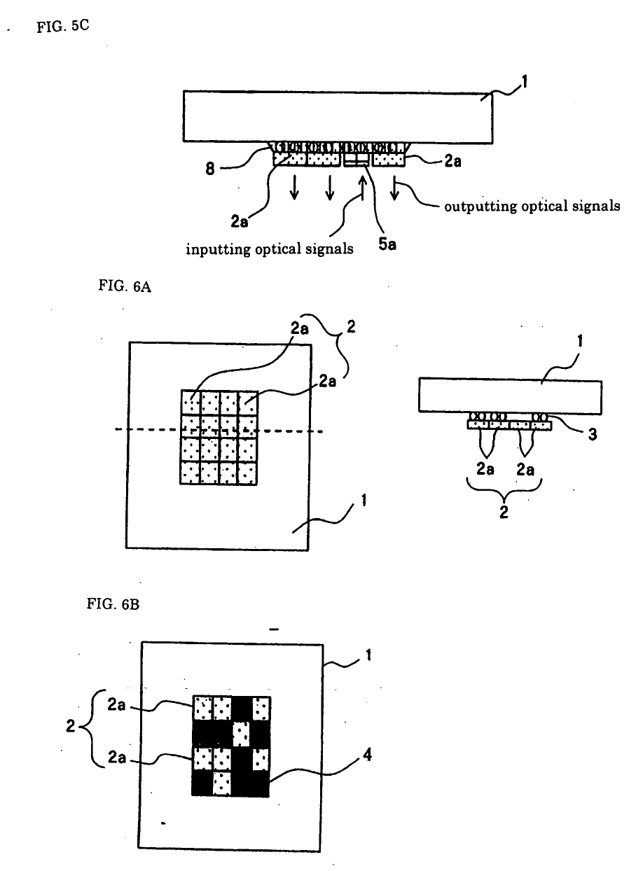

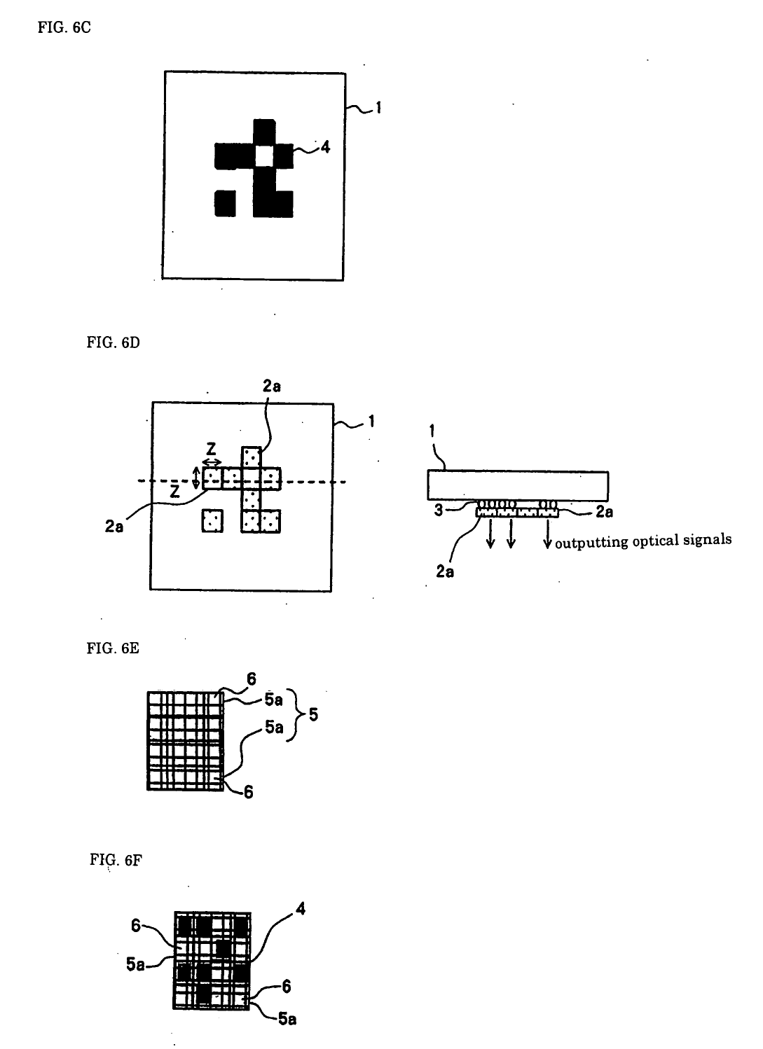

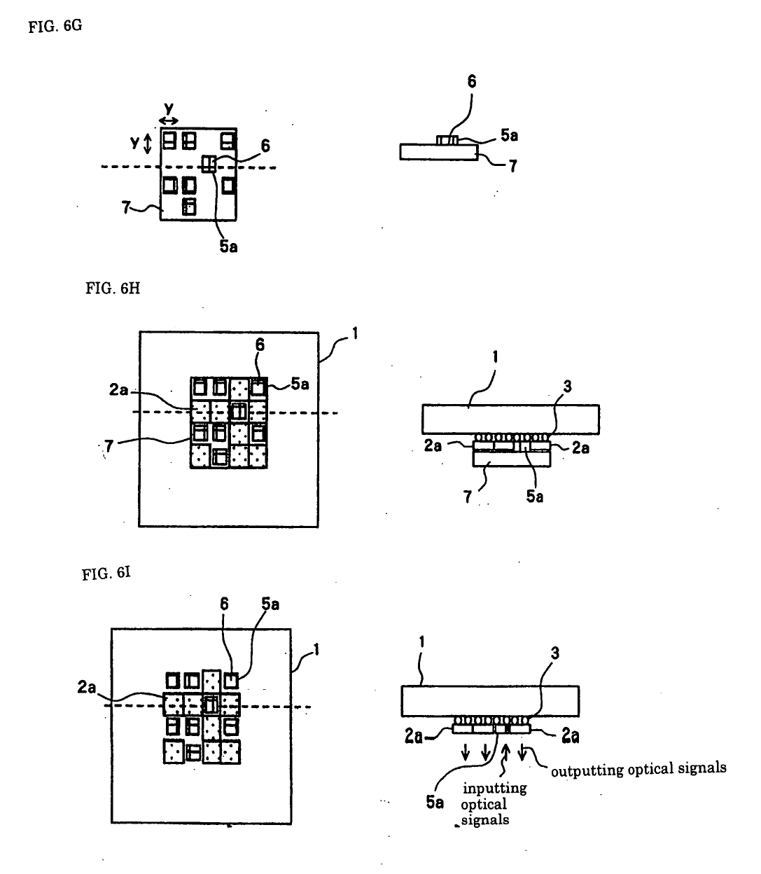

FIGS. 6A-6D show a fabrication method of the optical-element integrated LSI shown in FIGS. 5A and 5B. Although this explanation of a fabrication method takes as an example LSI 1 in which eight electrical signal output ports and eight electrical signal input ports are provided, the numbers of light-emitting devices and photodetectors can be modified as appropriate when the numbers of input/output ports of LSI 1 are different.

As shown in FIG. 6A, light-emitting device array 2 is prepared in which light-emitting devices 2a are arranged in four rows and four columns on the element substrate. Solder bumps 3 are formed on the pads of necessary light-emitting devices 2a among the plurality of light-emitting devices 2a that make up light-emitting device array 2, and solder bumps 3 that have been formed are used to electrically connect light-emitting device array 2 to LSI 1. In this case, “necessary light-emitting devices 2a” means light-emitting devices 2a that are to be mounted on electrical signal output ports of LSI 1. Light-emitting devices 2a that are not to be mounted on electrical signal output ports of LSI 1 are therefore placed on LSI 1 but are not electrically connected to LSI 1. In addition, the solder that is used for solder bumps 3 used for electrically connecting necessary light-emitting devices 2a to LSI 1 has a higher melting point than the solder of solder bumps 3 used for subsequently electrically connecting photodetectors 5a. This distinction in the use of solder can circumvent the problem of melting solder that connects light-emitting devices 2a in the subsequent step of electrically connecting photodetectors 5a.

Next, as shown in FIG. 6B, protective film 4 is formed to cover only necessary light-emitting devices 2a of light-emitting device array 2. In the present embodiment, protective film 4 is formed by patterning by, for example, exposing and developing a resist.

Unnecessary light-emitting devices 2a are next removed by etching as shown in FIG. 6C. Protective film 4 is then removed as shown in FIG. 6D.

Explanation next regards the steps for mounting photodetectors 5a with reference to FIGS. 6E-6I. First, as shown in FIG. 6E, photodetector array 5 is prepared in which photodetectors 5a are arranged in four rows and four columns on element substrate 7.

Next, as shown in FIG. 6F, protective film 4 is formed to cover only necessary photodetectors 5a among the plurality of photodetectors 5a that makes up photodetector array 5. In the present embodiment, protective film 4 is formed by patterning by, for example, exposing and developing a resist. In this case, “necessary photodetectors 5a” means photodetectors 5a that are to be subsequently mounted on electrical signal input ports of LSI 1.

As shown in FIG. 6G, unnecessary photodetectors 5a are next removed by etching. However, in this etching step, etching is applied only to functional portions 6 that are on the surface of unnecessary photodetectors 5a, and etching is not applied to element substrate 7. By this provision, element substrate 7 is used as a support for all of the plurality of photodetectors 5a.

Protective film 4 is next removed to obtain photodetector array 5 in which only necessary photodetectors 5a have functional portions 6. As shown in FIG. 6H, solder bumps 3 are next formed on the pads of the plurality of photodetectors 5a having functional portions 6, and solder bumps 3 that have been formed are used to electrically connect necessary photodetectors 5a with LSI 1.

Finally, element substrate 7 of photodetector array 7 is removed by etching as shown in FIG. 6I.

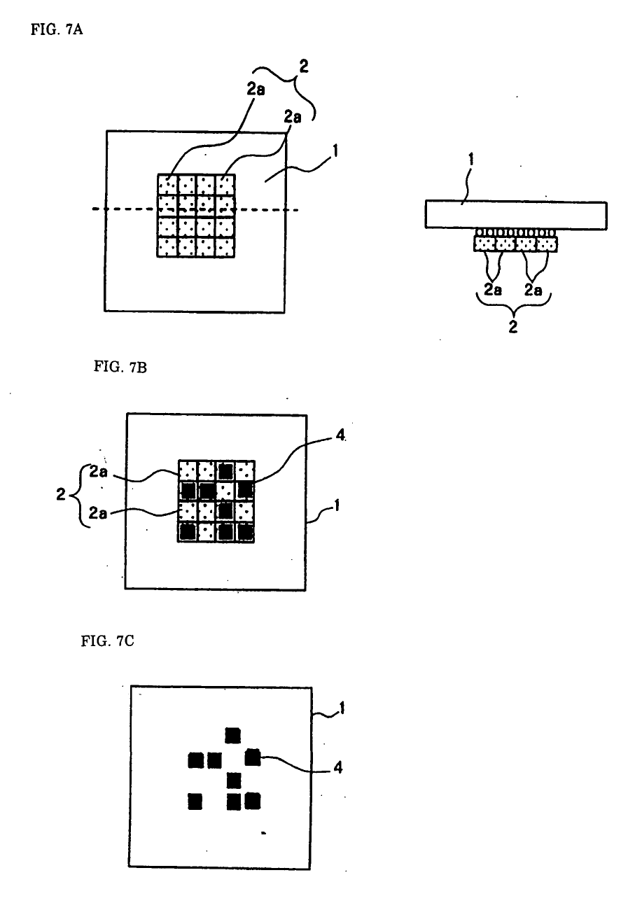

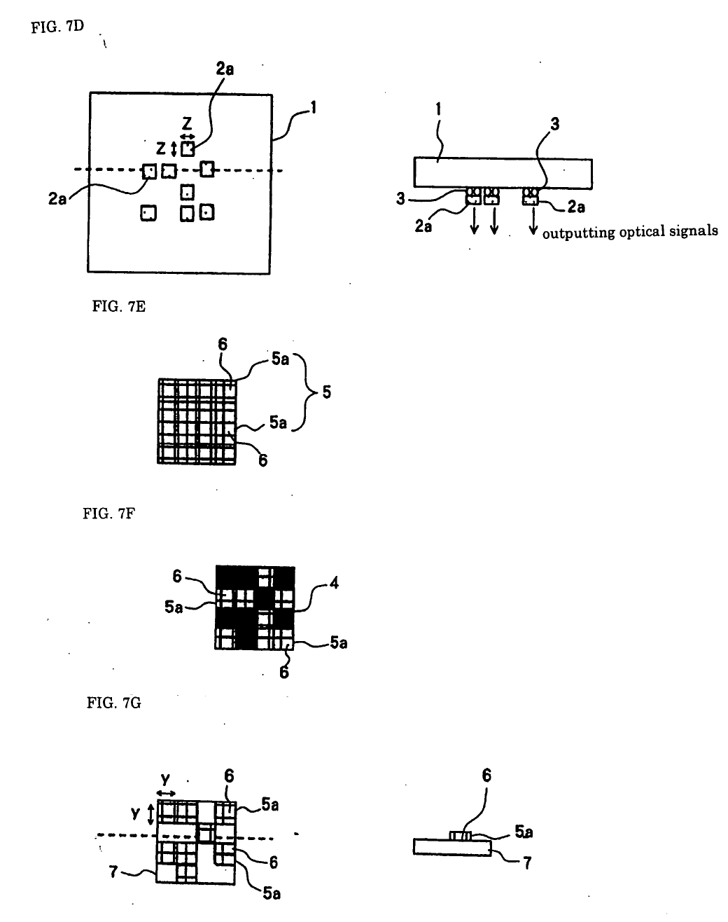

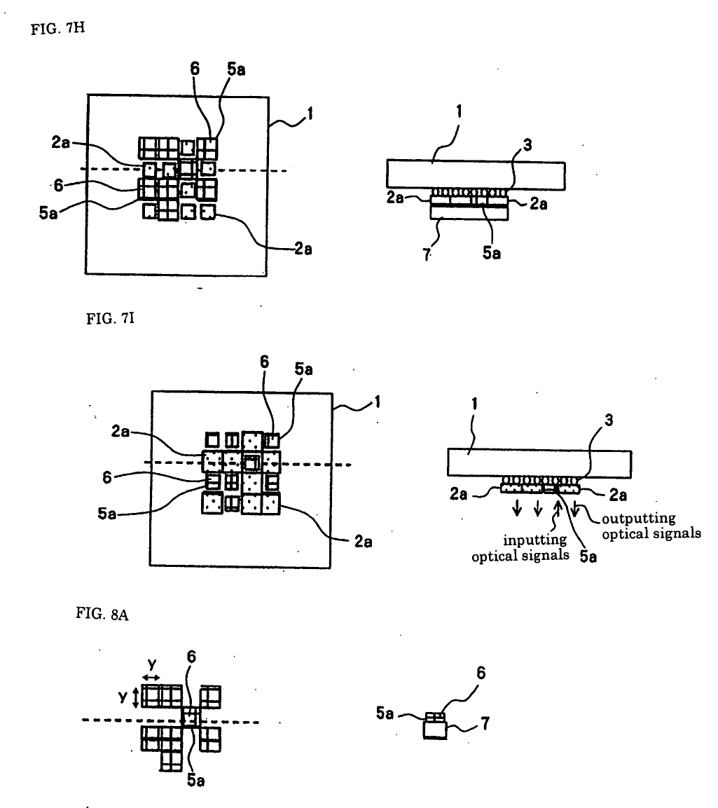

In this case, when the size of one channel of light-emitting device array 2 is z (see FIG. 6D) and the size of one channel of photodetector array 5 is y (see FIG. 6G), y is made smaller than z such that light-emitting devices 2a and photodetectors 5a do not interfere with each other during the above-described assembly. Even so, interference between light-emitting devices 2a and photodetectors 5a can be avoided by making z smaller than y. In FIGS. 7A-7I, an example is shown in which interference between light-emitting devices 2a and photodetectors 5a is circumvented by making z smaller than y.

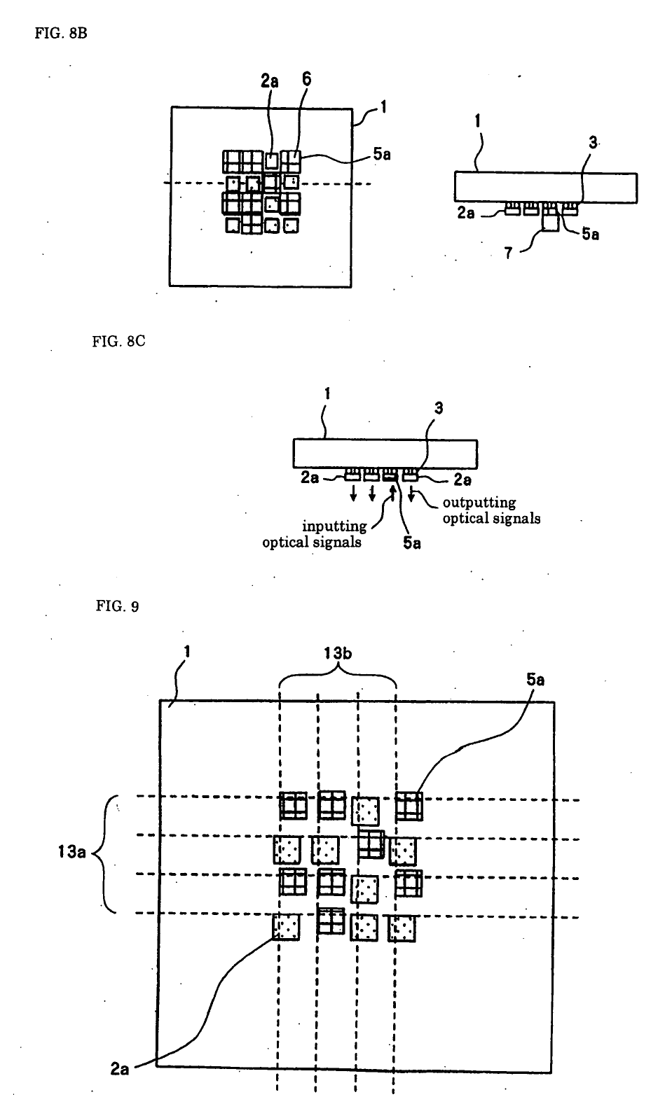

Up to this point, explanation has regarded a fabrication method in which, of unnecessary photodetectors among the plurality of photodetectors that make up photodetector array, only the functional portions are removed, and the element substrate is left intact. However, as shown in FIGS. 8A-8C, unnecessary photodetectors 5a can also be etched together with element substrate 7. This fabrication method eliminates the need to regulate the thickness of light-emitting devices 2a that are first mounted to avoid interference between light-emitting devices 2a and element substrate 7. The steps shown in FIGS. 8A-8C correspond to the steps shown in FIGS. 6G-6I. Accordingly, executing the steps shown in FIGS. 6A-6F and then executing the steps shown in FIGS. 8A-8C enables the fabrication of the optical-element integrated LSI shown in FIGS. 5A and 5B.

By means of the above-described fabrication method, an optical-element integrated LSI is fabricated in which light-emitting devices 2a and photodetectors 5a are mounted on each of a plurality of electrical signal output ports and electrical signal input ports, respectively, that are arranged at any positions of LSI 1. In this fabrication method, light-emitting device array 2 composed of a plurality of light-emitting devices 2a is mounted on LSI 1, following which unnecessary light-emitting devices 2a are removed while leaving behind necessary light-emitting devices 2a. Accordingly, light-emitting devices 2a are mounted as a group on all electrical signal output ports despite the random arrangement of the plurality of electrical signal output ports of LSI 1. As a result, the step of mounting light-emitting devices 2a is simplified, and this simplification contributes to lower costs. Further, the heights of the light-emitting surfaces of the plurality of light-emitting devices 2a that make up light-emitting device array 2 are aligned in advance, whereby the light-emitting surfaces of light-emitting devices 2a that have been mounted on each of the electrical signal output ports of LSI 1 are all the same height. Here, when the optical-element integrated LSI is optically coupled to optical circuits and optical signals are transmitted to or received from an outside LSI or memory, the incident surfaces of optical signals of each optical circuit are normally aligned to a uniform height. Thus, the uniformity of the height of the plurality of light-emitting devices 2a that are mounted on LSI 1 means that the spacing between each of light-emitting devices 2a and the plurality of optical circuits that are optically coupled to these devices can be kept uniform on all channels, and that highly efficient optical coupling can be realized between all light-emitting devices 2a and all optical circuits. The realization of highly efficient optical coupling means that the greater portion of emergent light from each light-emitting device 2a can be directed to the optical circuits, thereby obtaining the effects of enabling transmission over even greater distances, or for short-distance transmission, the effect of enabling high tolerance for noise.

Further, in the fabrication method of the present embodiment, photodetector array 5 in which functional portions 6 of unnecessary photodetectors 5a have been removed in advance is mounted on LSI 1, following which necessary photodetectors 5a are electrically connected to the electrical signal input ports of LSI 1. Accordingly, photodetectors 5a are mounted as a group on all electrical signal input ports despite the random arrangement of the plurality of electrical signal input ports of LSI 1, whereby the step of mounting photodetectors 5a is simplified, and this simplification contributes to lower costs. Further, the heights of the photoreception surfaces of the plurality of photodetectors 5a that make up photodetector array 5 are aligned in advance, whereby the photoreception surfaces of the plurality of photodetectors 5a that have been mounted on respective electrical signal input ports of LSI 1 are all the same height. When the optical-element integrated LSI is then optically coupled to optical circuits and optical signals are transmitted to and received from an outside LSI or memory, the emergent surfaces of optical signals of each optical circuit are normally aligned to a uniform height. The uniformity of height of the plurality of photodetectors 5a that are mounted on LSI 1 means that the spacing between each of photodetectors 5a and the plurality of optical circuits that are optically coupled to these devices can be kept uniform on all channels, and further, that highly efficient optical coupling can be realized between all photodetectors 5a and all optical circuits. Still further, the realization of highly efficient optical coupling means that the greater portion of emergent light from each optical circuit is photodetected by each photodetector 5a, whereby even weak optical signals that were difficult or impossible to receive in the prior art can be received. For example, the present embodiment enables the reception of even a weak optical signal that has been attenuated by long-distance transmission. Alternatively, because the greater portion of an optical signal having a comparatively strong light intensity is received by photodetector 5a, transmission can be realized that is strongly resistant to noise. The later effect is particularly conspicuous in transmissions over short distances.

Generally, an optical-element integrated LSI fabricated by this fabrication method is not only provided with both light-emitting devices and photodetectors, but is also configured such that the heights of each light-emitting device and each photodetector are uniformly aligned. Accordingly, the effects can be obtained that highly efficient optical coupling with optical circuits can be realized on all channels on the light-emitting side and on the light-receiving side and that optical communication can be carried out under excellent conditions for both transmission and reception.

In addition, when a plurality of light-emitting devices and photodetectors are mounted in a group as in the fabrication method of the present embodiment, the following effects are obtained. FIG. 9 is a schematic plan view of an optical-element integrated LSI that has been fabricated by this fabrication method. The actual mounting positions of photodetectors 5a are shifted upward from the prescribed mounting positions (shown by dotted lines 13a in the figure). In addition, the actual mounting positions of light-emitting devices 2a are shifted to the left from the prescribed mounting positions (shown by dotted lines 13b in the figure). However, the plurality of photodetectors 5a and light-emitting devices 2a are both mounted as a group on LSI 1. Accordingly, the direction and distance of the shift of the actual mounting positions with respect to the prescribed mounting positions is the same among the plurality of elements. In other words, in FIG. 9, all photodetectors 5a are shifted by the same distance upward with respect to the prescribed mounting positions. In addition, all light-emitting devices 2a are shifted by the same distance to the left from the prescribed mounting positions. In this case, highly efficient coupling is realized if all optical parts such as lenses (not shown) that correspond to each of photodetectors 5a are shifted upward. Further, highly efficient coupling is realized if all optical parts corresponding to each of light-emitting devices 2a are shifted to the left.

As described in the foregoing explanation, in an optical-element integrated LSI that has been fabricated by this fabrication method in which a plurality of photodetectors and light-emitting devices are mounted as a group on an LSI, the positional shift between the actual mounting positions of the plurality of similar optical elements and the designed mounting positions is in the same direction and distance for all optical elements. As a result, shifting the positions of optical circuits that are to be optically coupled to the optical elements in the same direction and by the same distance as the positional shift of the optical elements can produce highly efficient optical coupling between the optical elements and optical circuits. However, this effect is limited to a plurality of identical optical elements. In the case shown in FIG. 9, the effect is limited to either optical coupling between light-emitting devices 2a and optical circuits or optical coupling between photodetectors 5a and optical circuits. Of course, when light-emitting devices 2a and photodetectors 5a are both shifted the same direction and same distance, highly efficient coupling can be realized for all optical elements and optical circuits.

By successively lowering the melting point of the solder used in the mounting of optical elements with the progression of fabrication steps, soldering can be executed in succeeding steps at a temperature that does not melt the solder used for soldering in earlier steps. This approach circumvents the problem in which solder melts during a fabrication step and causes shifting of the positions of optical elements that have been previously mounted. More specifically, when a plurality of light-emitting devices are first mounted and a plurality of photodetectors mounted next, solder having a melting point higher than the solder used in the mounting of photodetectors is used for mounting the light-emitting devices. By adopting this approach, when mounting photodetectors after the light-emitting devices have been mounted, the solder used in mounting the light-emitting devices does not melt, and no shifting occurs in the positions of the light-emitting devices. By selectively using solder having different melting points as described hereinabove, light-emitting devices and photodetectors can be reliably secured to prescribed positions.

In addition, as shown in FIG. 5C, the use of underfill resin 8 to fill gaps between LSI 1 and light-emitting devices 2a and photodetectors 5a can increase the connection strength between these components. The process of inserting underfill resin 8 can be added to any step within the above-described fabrication steps.

### Fourth Embodiment

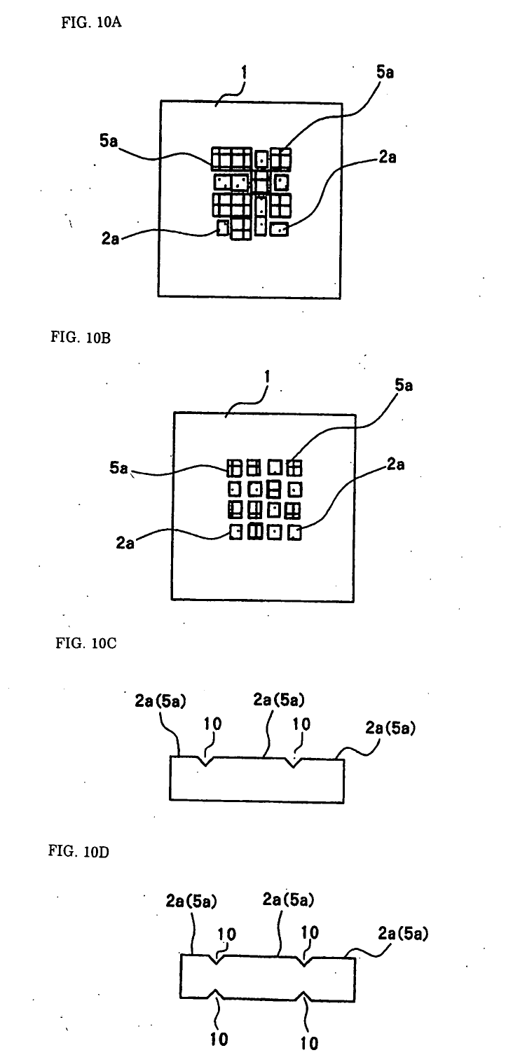

FIGS. 10A and 10B show another optical-element integrated LSI of the present invention. In the optical-element integrated LSI that is shown in FIG. 10A, a portion of adjacent photodetectors 5a are linked to each other. A portion of the electrode pattern of each of photodetectors 5a that make up photodetector array 5 straddles two or more channels, and when division of electrode patterns that straddle channel gaps is not desirable, a configuration such as shown in FIG. 10A is preferable. FIG. 10A shows an example that includes both portions in which photodetectors 5a are linked and portions in which photodetectors 5a are separated, the same states holding true for the light-emitting devices. On the other hand, in the optical-element integrated LSI shown in FIG. 10B, gaps are provided between adjacent light-emitting devices 2a and photodetectors 5a, and optical elements are independent for each channel. When the stress that acts upon optical elements due to the effect of thermal expansion is preferably reduced to a minimum, the configuration shown in FIG. 10B is preferable. The interposition of grooves 10 between adjacent optical elements as shown in FIG. 10C or FIG. 10D can be considered as an example of a method for providing gaps between adjacent optical elements and for facilitating separation between adjacent optical elements as shown in FIG. 10B. FIGS. 10C and 10D give a schematic representation of the profile of optical elements, FIG. 10C showing the provision of grooves 10 on one surface of the optical elements and FIG. 10D showing the provision of grooves 10 on both surfaces of the optical elements.

As described in the foregoing explanation, the adoption of a structure in which the plurality of mounted optical elements are linked to each other allows sharing of electrode wiring between adjacent optical elements and increases the freedom of the wiring layout. Such a configuration further increases the degree of freedom regarding whether mounting is realized by arranging solder on each electrode. On the other hand, the adoption of a structure in which optical elements are separated for each channel enables a reduction of the stress that acts upon optical elements due to the difference in the coefficient of thermal expansion between the LSI and the optical elements.

### Fifth Embodiment

FIGS. 11A and 11B show another example of an optical-element integrated LSI of the present invention. In the optical-element integrated LSI shown in FIG. 11A, the heights of a plurality of photodetectors 5a are uniform with respect to LSI 1, and the heights of a plurality of light-emitting devices 2a are also uniform with respect to LSI 1. However, the heights of light-emitting devices 2a and photodetectors 5a are different. The optical-element integrated LSI shown in FIG. 11A can be fabricated by first mounting light-emitting devices 2a on LSI 1 and then mounting photodetectors 5a on LSI 1. Here, setting the thickness of photodetectors 5a greater than that of light-emitting devices 2a enables the mounting of light-emitting devices 2a and photodetectors 5a without interference between the two.

In the optical-element integrated LSI shown in FIG. 11B, the heights of the plurality of photodetectors 5a and light-emitting devices 2a are uniform with respect to LSI 1. In other words, the heights of all optical elements are identical. An optical-element integrated LSI such as shown in FIG. 11B can be fabricated by fabricating the optical-element integrated LSI of the structure shown FIG. 11A and then aligning thick optical elements (photodetectors 5a in FIG. 11A) to thin optical elements (light-emitting devices 2a shown in FIG. 11A) by etching.

The advantages realized by aligning the heights of mounted optical elements as shown in FIGS. 11A and 11B have been repeatedly explained thus far, and further explanation is therefore here omitted.

### Sixth Embodiment

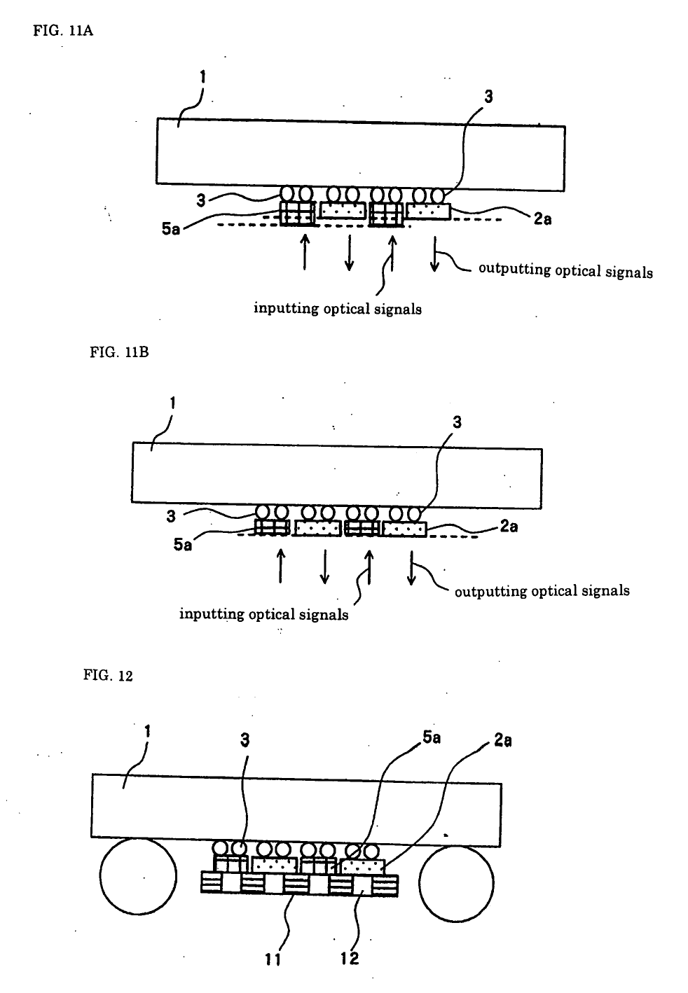

FIG. 12 shows another example of an optical-element integrated LSI of the present invention. In the optical-element integrated LSI shown in FIG. 12, a plurality of light-emitting devices 2a and photodetectors 5a are mounted on LSI 1 by means of solder bumps 3, and heat sinks 11 are provided in the proximity of these light-emitting devices 2a and photodetectors 5a. Various materials such as aluminum, copper, and silicon can be used as the material of heat sinks 11. Although there is no problem when the material of heat sinks 11 is optically transparent to the wavelength of the input and output light of light-emitting devices 2a and photodetectors 5a, when the material is not transparent, windows 12 must be formed to maintain light paths.

It is known that as the temperature of optical elements such as light-emitting devices and photodetectors rises, performance deteriorates compared to performance at normal temperature. However, the heat that is generated from light-emitting devices 2a and photodetectors 5a is radiated by heat sinks 11 provided in the proximities of light-emitting devices 2a and photodetectors 5a according to the optical-element integrated LSI of this example, whereby light-emitting devices 2a and photodetectors 5a can be operated at a temperature close to normal temperature. As a result, the performance of light-emitting devices 2a and photodetectors 5a is adequately exhibited. In addition, providing similar heat sinks on the sides of LSI 1 enables an even greater radiation effect.

### Seventh Embodiment

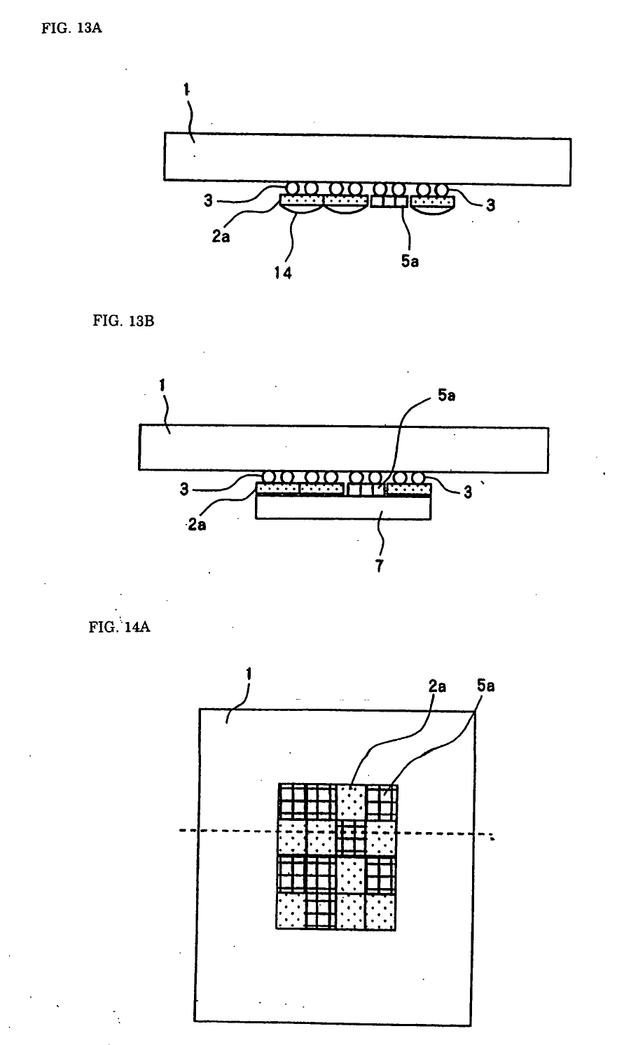

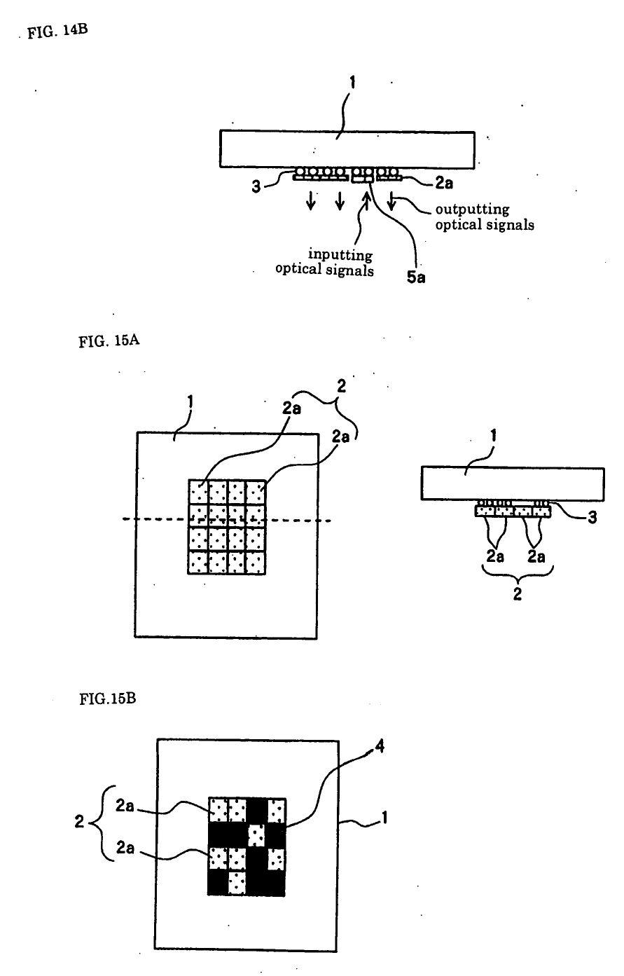

FIG. 13A shows another example of an optical-element integrated LSI of the present invention. In the optical-element integrated LSI shown in FIG. 13A, a plurality of light-emitting devices 2a and photodetectors 5a are mounted on LSI 1, and lenses 14 are integrated with all or a portion of light-emitting devices 2a. The focusing action of lenses 14 suppresses the divergence of light that emerges from light-emitting devices 2a, and further, collimates the light to facilitate the highly efficient direction of light to optical components that are the targets of coupling. In addition, if necessary, lenses can also be integrated with photodetectors 5a. With the trend toward higher speeds of photodetectors 5a, the miniaturization of light-receiving parts is advancing, and the integration of lenses is therefore effective for realizing highly efficient optical coupling. The method of integrating lenses with light-emitting devices 2a and photodetectors 5a includes a method of etching element substrate 7 on which photodetectors 5a are formed to realize a convex shape as shown in FIG. 13B; and also includes a method of applying a polymer to light-emitting devices 2a or photodetectors 5a, and then curing the polymer, taking advantage of the surface tension of the polymer to form a lens shape.

The provision of a lens on an optical element can suppress the divergence of light that emerges from the optical element or the light that emerges from an optical circuit. In addition, the properties of the optics of, for example, a lens can produce parallel rays. As a result, highly efficient optical coupling can be realized despite a considerable distance between the optical element and the optical circuit. Alternatively, highly efficient optical coupling is realized even when the area of the photoreception part of a photodetector is small or when the optical propagation part (normally referred to as the “core”) of an optical circuit is small.

### Eighth Embodiment

FIGS. 14A and 14B show another example of an optical-element integrated LSI of the present invention. In the optical-element integrated LSI shown in FIGS. 14A and 14B, a plurality of light-emitting devices 2a and photodetectors 5a are mounted on LSI 1. Explanation here regards an example in which eight electrical signal output ports and eight electrical signal input ports are provided on LSI 1, but the number of light-emitting devices and photodetectors can be modified as appropriate when the number of input/output ports are different. Light-emitting devices 2a and photodetectors 5a are made thin film while leaving the functional portions. In this case, the functional portions of photodetectors 5a are as previously described. “Functional portions” of light-emitting devices 2a refers to those parts necessary for carrying out the functions of converting electrical signals that are received as input to optical signals and supplying the converted optical signals as output.

As previously described, to make light-emitting devices 2a and photodetectors 5a thin films can shorten the distance between these optical elements and the objects of optical coupling and can improve the coupling efficiency and permissible amount of positional shift. In addition, the thinning of the films removes the substrate portion of the optical elements and can eliminate loss that is produced when light is transmitted through the substrate.

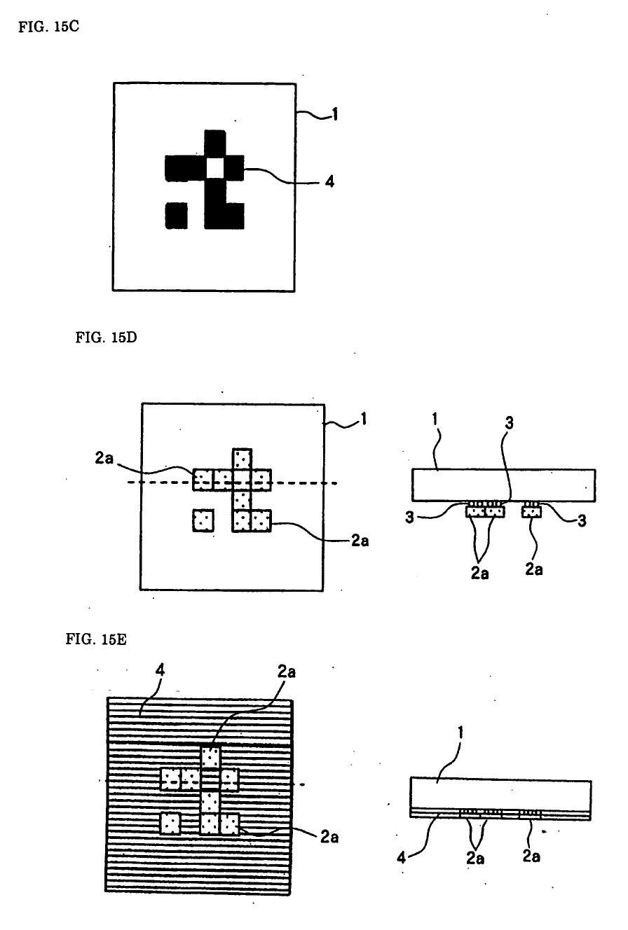

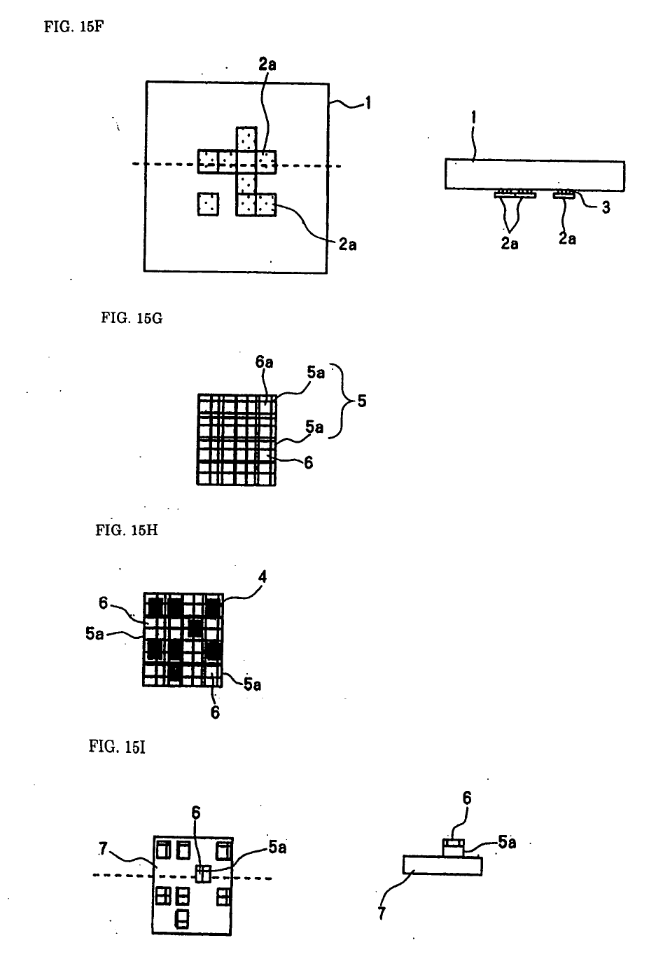

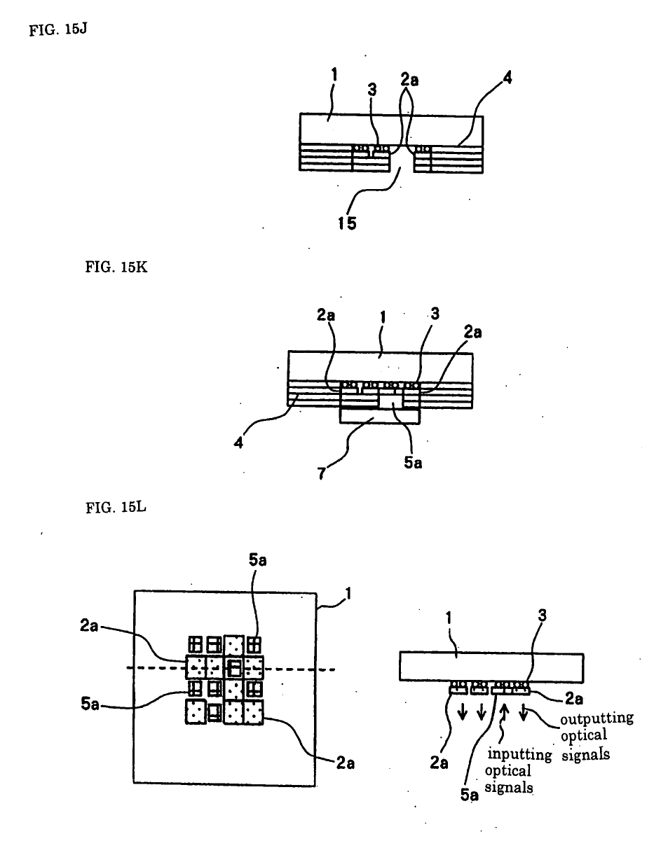

FIGS. 15A-15L show a fabrication method of the optical-element integrated LSI shown in FIGS. 14A and 14B. First, as shown in FIG. 15A, light-emitting device array 2 is prepared in which light-emitting devices 2a are arranged in four rows and four columns on the element substrate (not shown). Solder bumps 3 are formed only on pads of necessary light-emitting devices 2a in light-emitting device array 2, and solder bumps 3 that have been formed are used to electrically connect light-emitting device array 2 and LSI 1. “Necessary light-emitting devices 2a” refers to light-emitting devices 2a that are to be mounted on electrical signal output ports of LSI 1.

Next, as shown in FIG. 15B, protective film 4 is formed to cover only light-emitting devices 2a for which solder bumps 3 have been formed. In this example, protective film 4 is formed by patterning by, for example, exposing and developing a resist.

As shown in FIG. 15C, unnecessary light-emitting devices 2a are next removed by etching, following which, as shown in FIG. 15D, protective film 4 is removed, whereby light-emitting devices 2a are mounted only at necessary positions.

Next, as shown in FIG. 15E, the surface of LSI 1 on which light-emitting devices 2a are not mounted is covered by protective film 4, following which the element substrate of light-emitting devices 2a is etched to produce thin-film light-emitting devices 2a. Protective film 4 is subsequently removed as shown in FIG. 15F.

Next, as shown in FIG. 15G, photodetector array 5 is prepared in which photodetectors 5a are arranged in four rows and four columns on element substrate 7. Protective film 4 is next formed to cover only necessary photodetectors 5a as shown in FIG. 15H. In this example, protective film 4 is formed by patterning by, for example, exposing and developing a resist. “Necessary photodetectors 5a” refers to photodetectors 5a that are to be subsequently mounted on LSI 1.

Next, as shown in FIG. 15I, unnecessary photodetectors 5a are removed by etching. In this etching step, however, etching is applied to both the surface of photodetectors 5a and to portions of the surface of element substrate 7. However, etching is not applied to entire element substrate 7, and portions are left unchanged. This method is adopted to allow the use of element substrate 7 as a support for the entirety of the plurality of photodetectors 5a. Protective film 4 is then removed to obtain photodetector array 5 in which photodetectors 5a are left only in necessary positions. Solder bumps 3 are further formed on the pads of the plurality of photodetectors 5a that are left.

Next, as shown in FIG. 15J, openings 15 are provided on pads of LSI 1 on which light-emitting devices 2a are already mounted, these openings 15 leading to the electrical signal input ports to which photodetectors 5a are to be electrically connected. Other portions are covered by protective film 4. Then, as shown in FIG. 15K, photodetector array 5 is placed on LSI 1 such that each photodetector 5a of photodetector array 5 is inserted into a corresponding opening 15, whereby a plurality of photodetectors 5a are mounted as a group. Next, as shown in FIG. 15L, element substrate 7 of photodetector array 5 is etched, following which protective film 4 that is provided on the LSI 1 side is removed.

As another fabrication method, unnecessary light-emitting devices 2a among the plurality of light-emitting devices 2a that make up light-emitting device array 2 are first removed, following which light-emitting devices 2a are mounted on the electrical signal output ports of LSI 1, and photodetectors 5a are mounted by the same method as described above.

The fabrication method described above enables the fabrication of an optical-element integrated LSI that is provided with optical elements of a thin-film structure. An optical-element integrated LSI provided with optical elements of a thin-film structure shortens the distance between the functional portions of optical elements and the optical circuits that are optically coupled with these functional portions. Optical signals that emerge from light-emitting devices or optical circuits can thus be directed to optical circuits and photodetectors before diffusion to raise the optical coupling efficiency.

### Ninth Embodiment

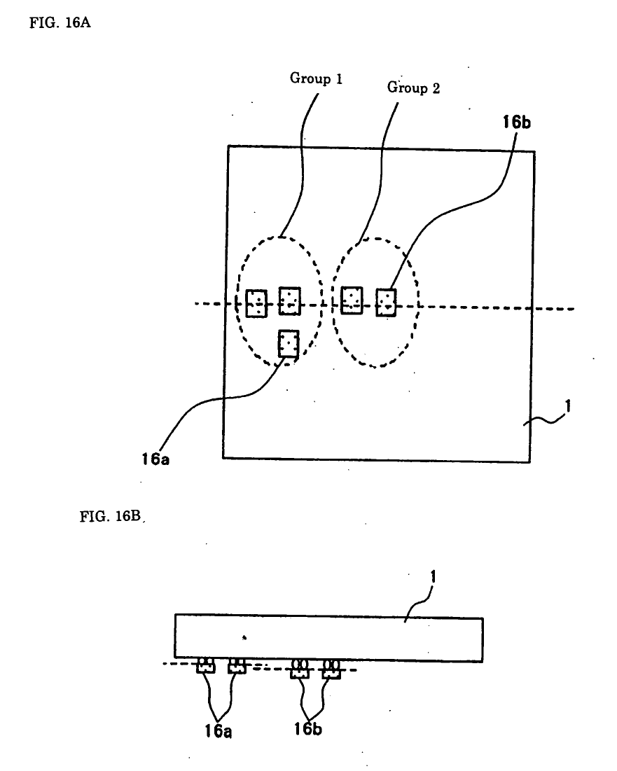

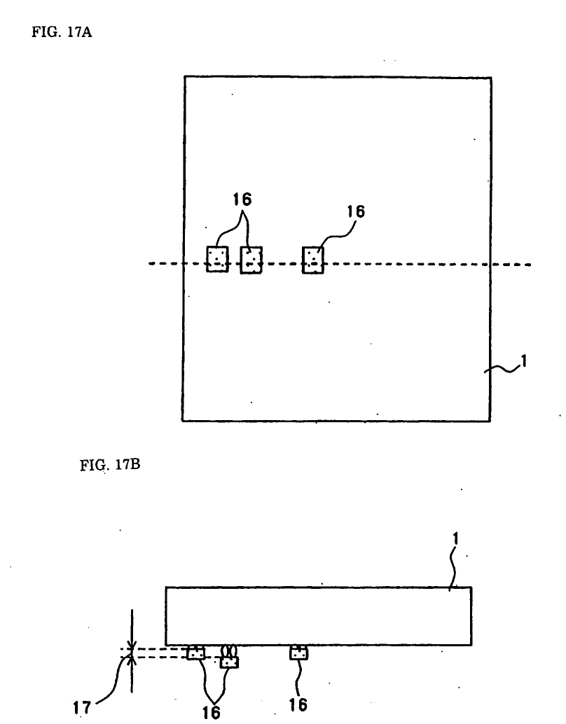

FIGS. 16A and 16B show another example of an optical-element integrated LSI of the present invention. In the optical-element integrated LSI shown in FIGS. 16A and 16B, five optical elements are mounted on LSI 1. Of these optical elements, three optical elements 16a are linked at the left side of LSI 1, and these are referred to as group 1. The remaining two optical element 16b are linked at approximately the center of LSI 1, and these are referred to as group 2. Optical elements 16a and 16b that belong to group 1 and group 2 are identical optical elements.

The three optical elements 16a that belong to group 1 have uniform heights, and the two optical elements 16b that belong to group 2 have uniform heights. However, optical elements 16a are lower than optical elements 16b. Accordingly, when the position of optical fibers (not shown) that are optically coupled to optical elements 16a that belong to group 1 is higher than the position of optical fibers (not shown) that are optically coupled to optical elements 16b that belong to group 2, the distance between the optical fiber and optical elements 16a that belong to group 1 is substantially equal to the distance between the optical fiber and optical elements 16b that belong to group 2 if the height of optical elements 16a that belong to group 1 is set lower than the height of optical elements 16b that belong to group 2. As a result, the optical coupling efficiency is uniform and higher efficiency is obtained.

As described hereinabove, when the heights of optical circuit groups that are to be optically coupled differ according to the optical elements that belong to each group, setting the height of the optical elements that belong to each group to match the height of the corresponding optical circuit group realizes highly efficient optical coupling between the optical circuits and the optical elements that belong to each group, and further, realizes excellent optical communication.

### Tenth Embodiment

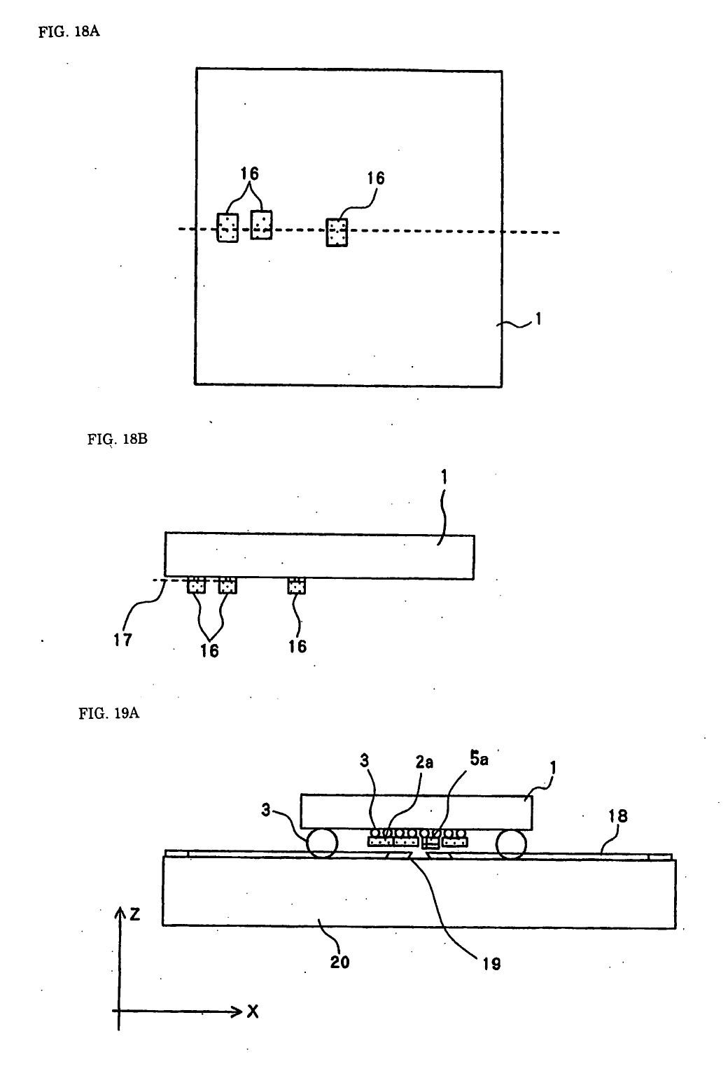

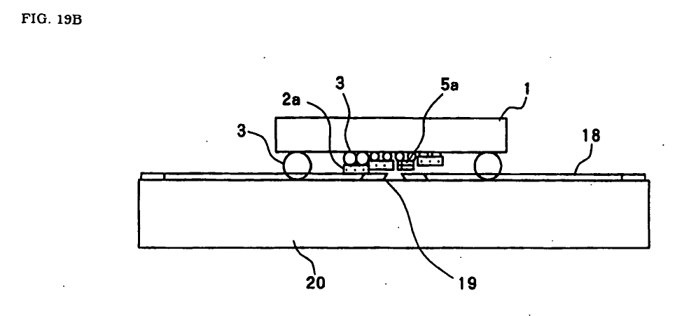

FIGS. 17A and 17B and FIGS. 18A and 18B show an optical-element integrated LSI in which three optical elements 16 are mounted on LSI 1. Of these, the optical-element integrated LSI shown in FIGS. 17A and 17B has been fabricated by a fabrication method of the prior art in which a plurality of optical elements are individually mounted. On the other hand, the optical-element integrated LSI shown in FIGS. 18A and 18B has been fabricated by the fabrication method of the present invention in which a plurality of optical elements have been mounted as a group. When the height of LSI 1 is taken as a standard in the optical-element integrated LSI shown in FIGS. 17A and 17B, height discrepancy 17 between adjacent optical elements 16 is approximately 2 μm, and cases frequently occur in which the discrepancy in height exceeds this level due to the state of the device. In contrast, in the optical-element integrated LSI shown in FIGS. 18A and 18B, height discrepancy 17 between neighboring adjacent optical elements 16 is suppressed to approximately 0.5 μm. This large decrease in the discrepancy in height is realized because, in the fabrication method of the present invention, necessary optical elements have been mounted as a group by removing unnecessary optical elements after first mounting the optical element array that is made up from a plurality of optical elements, or because necessary optical elements have been mounted as a group by mounting an optical element array from which unnecessary optical elements have been removed in advance. As yet another effect, mounting a plurality of optical elements as a group enables a shortening of the time required for mounting compared to mounting the optical elements one at a time, and further, enables a reduction of costs. These effects increase with an increase in the number of optical elements that are mounted.

### Eleventh Embodiment

FIGS. 19A and 19B show cross-sections of the structure when an optical-element integrated LSI is mounted on optoelectronic hybrid substrate 20 on which optical waveguide 18, optical waveguide end-face mirror 19, and electrical wiring have been formed. In this case, “optoelectronic hybrid substrate 20” refers to a substrate that is provided with both optical circuits and electrical circuits. FIGS. 19A and 19B show an example that uses optical waveguide 18 as the optical circuit, but optical fiber may also be used as other optical circuits. FIG. 19A shows the cross-section of the structure of optoelectronic hybrid substrate 20 on which the optical-element integrated LSI of the present invention has been mounted. FIG. 19B shows the cross-sectional structure of optoelectronic hybrid substrate 20 on which an optical-element integrated LSI of the prior art has been mounted.

The optical-element integrated LSI shown in FIG. 19A and the optical-element integrated LSI shown in FIG. 19B are similar in that in both cases, light-emitting devices 2a for three channels and photodetector 5a for one channel are mounted on LSI 1. However, as is clear from a comparison of FIGS. 19A and 19B, the heights of light-emitting devices 2a and photodetector 5a are uniformly aligned in the optical-element integrated LSI of the present invention in which a plurality of light-emitting devices 2a and photodetector 5a have been mounted as a group. In the optical-element integrated LSI of the prior art in which light-emitting devices 2a and photodetector 5a have been mounted on LSI 1 for one channel at a time, variations in height occur between each of the optical elements.

Optical waveguide 18 and optical waveguide end-face mirror 19 are formed on the surface of optoelectronic hybrid substrate 20, and electrical wiring (not shown) is further formed. In addition, the optical-element integrated LSI and optoelectronic hybrid substrate 20 are electrically connected using solder bumps 3, and optical coupling is achieved by aligning the positions of optical waveguide end-face mirror 19 and the photodetector of optical-element integrated LSI in the X, Y, and Z directions. Here, the X direction is parallel to the surface of optoelectronic hybrid substrate 20, the Y direction is perpendicular to the page surface, and the Z direction is perpendicular to the surface of optoelectronic hybrid substrate 20. FIGS. 19A and 19B show sectional views in the X and Z directions. Comparatively low-speed signals are received as input and delivered as output between optoelectronic hybrid substrate 20 and the optical-element integrated LSI by way of solder bumps 3; and high-speed signals are received as input and delivered as output by way of light-emitting devices 2a, photodetectors 5a, and optical waveguide 18.

Here, in order to optically couple optical signals that are supplied from an optical-element integrated LSI at high efficiency, and moreover, with the same efficiency for all channels, the relative positions of each optical element and optical waveguide end-face mirror 19 must be aligned for each channel. Regarding this point, if the optical-element integrated LSI of the present invention in which the heights of a plurality of optical elements are uniform with respect to LSI 1 is mounted parallel to optoelectronic hybrid substrate 20, and moreover, is mounted with the optical axes of optical elements and optical waveguide end-face mirrors 19 in alignment, the distances (in the Z direction) between each optical element and optical waveguide end-face mirror 19 will be uniform. As a result, optical coupling that is uniform and highly efficient will be realized for all channels. In addition, the strength of the plurality of optical signals that are supplied from the optical-element integrated LSI will be uniformly improved, and the transmission distance is therefore extended for all channels.

In contrast, when the heights of the plurality of optical elements are not uniform with respect to LSI 1 as in the optical-element integrated LSI of the prior art shown in FIG. 19B, even when the optical-element integrated LSI is mounted parallel to optoelectronic hybrid substrate 20, the distance (in the Z direction) between each optical element and optical waveguide end-face mirror 19 will not be uniform and variation will occur in optical coupling. As a result, the distance that optical signals can be transmitted will vary and the transmission distance will be short for channels in which the optical coupling efficiency is poor.

1. An optical-element integrated semiconductor integrated circuit wherein two or more optical elements for converting electrical signals, that are the input to and the output from a semiconductor integrated circuit, to optical signals are mounted on said semiconductor integrated circuit; wherein the heights of said two or more optical elements are identical.

2. An optical-element integrated semiconductor integrated circuit wherein two or more optical elements for converting electrical signals, that are the input to and the output from a semiconductor integrated circuit, to optical signals are mounted on said semiconductor integrated circuit; wherein:
said two or more optical elements are divided into two or more groups; and
the heights of optical elements that belong to the same group are identical, but the heights of optical elements that belong to different groups are different.

3. An optical-element integrated semiconductor integrated circuit according to claim 1, wherein the melting point of solder that secures a portion of said two or more optical elements to said semiconductor integrated circuit differs from the melting point of solder that secures other optical elements to said semiconductor integrated circuit.

4. An optical-element integrated semiconductor integrated circuit according to claim 2, wherein the melting point of solder that secures a portion of said two or more optical elements to said semiconductor integrated circuit differs from the melting point of solder that secures other optical elements to said semiconductor integrated circuit.

5. An optical-element integrated semiconductor integrated circuit comprising:
a semiconductor integrated circuit having two or more electrical signal output ports arranged irregularly; and
two or more light-emitting devices connected to the corresponding said electrical signal output ports of said semiconductor integrated circuit for converting electrical signals supplied as output from a corresponding electrical signal output port to an optical signal and supplying these optical signals to the outside;
wherein the heights of the light-emitting surfaces of said two or more light-emitting devices that are connected to said electrical signal output ports are identical.

6. An optical-element integrated semiconductor integrated circuit comprising:
a semiconductor integrated circuit having two or more electrical signal input ports arranged irregularly; and
two or more photodetectors connected to the corresponding said electrical signal input ports of said semiconductor integrated circuit for converting optical signals received as input from the outside to electrical signals and supplying these electrical signals to corresponding electrical signal input ports;
wherein the heights of the photoreception surfaces of said two or more photodetectors that are connected to said electrical signal input ports are identical.

7. An optical-element integrated semiconductor integrated circuit comprising:
a semiconductor integrated circuit having two or more irregularly arranged electrical signal output ports and electrical signal input ports;
two or more light-emitting devices connected to corresponding electrical signal output ports of said semiconductor integrated circuit for converting electrical signals supplied as output from corresponding electrical signal output ports to optical signals and supplying these optical signals to the outside; and
two or more photodetectors connected to corresponding electrical signal input ports of said semiconductor integrated circuit for converting optical signals received as input from the outside to electrical signals and supplying these electrical signals to the corresponding said electrical signal input ports;
wherein the heights of the light-emitting surfaces of said two or more light-emitting devices that are connected to said electrical signal output ports are identical, and the heights of the photoreception surfaces of said two or more photodetectors that are connected to said electrical signal input ports are identical.

8. A optical-element integrated semiconductor integrated circuit according to claim 7, wherein the heights of said light-emitting surfaces of said light-emitting devices connected to said electrical signal output ports and the heights of said photoreception surfaces of said photodetectors connected to said electrical signal input ports are identical to each other.

9. An optical-element integrated semiconductor integrated circuit according to claim 7, wherein the melting point of solder that secures said light-emitting devices to said semiconductor integrated circuit differs from the melting point of solder that secures said photodetectors to said semiconductor integrated circuit.

10. An optical-element integrated semiconductor integrated circuit according to claim 5, wherein an optics element for focusing light emitted from the light-emitting surface is provided in at least one of said light-emitting devices.

11. An optical-element integrated semiconductor integrated circuit according to claim 7, wherein an optics element for focusing light emitted from the light-emitting surface is provided in at least one of said light-emitting devices.

12. An optical-element integrated semiconductor integrated circuit according to claim 6, wherein an optics element for focusing light that is received from the outside toward said photoreception surface is provided in at least one of said photodetectors.

13. An optical-element integrated semiconductor integrated circuit according to claim 7, wherein an optics element for focusing light that is received from the outside toward said photoreception surface is provided in at least one of said photodetectors.

14. An optical-element integrated semiconductor integrated circuit according to claim 5, wherein said two or more light-emitting devices or photodetectors have a common electrode pattern.

15. An optical-element integrated semiconductor integrated circuit according to claim 6, wherein said two or more light-emitting devices or photodetectors have a common electrode pattern.

16. An optical-element integrated semiconductor integrated circuit according to claim 7, wherein said two or more light-emitting devices or photodetectors have a common electrode pattern.

17. An fabrication method of an optical-element integrated semiconductor integrated circuit in which two or more optical elements for converting electrical signals, that are the input to or output from a semiconductor integrated circuit, to optical signals are mounted on said semiconductor integrated circuit; said fabrication method including optical element mounting steps comprising steps of:
forming bumps on necessary optical elements in an optical element array;
using said bumps to mount said optical element array on said semiconductor integrated circuit and to connect said necessary optical elements to said semiconductor integrated circuit;
covering said necessary optical elements that have been connected to said semiconductor integrated circuit with a protective film;
removing unnecessary optical elements that are not covered by said protective film from said optical element array; and
removing said protective film.

18. A fabrication method of an optical-element integrated semiconductor integrated circuit in which two or more optical elements for converting electrical signals, that are the input to and output from a semiconductor integrated circuit, to optical signals are mounted on said semiconductor integrated circuit; said fabrication method including optical element mounting steps comprising steps of:
covering necessary optical elements in an optical element array with a protective film;
removing the functional portions of unnecessary optical elements that are not covered by said protective film;
removing said protective film; and
mounting said optical element array, in which the functional portions of said unnecessary optical elements have been removed, on said semiconductor integrated circuit, and connecting said necessary optical elements to said semiconductor integrated circuit.

19. A fabrication method of an optical-element integrated semiconductor integrated circuit in which two or more optical elements for converting electrical signals, that are the input to and output from a semiconductor integrated circuit, to optical signals are mounted on said semiconductor integrated circuit; said fabrication method comprising:
a first optical element mounting step that includes steps of:
forming bumps on necessary optical elements in an optical element array;
using said bumps to mount said optical element array to said semiconductor integrated circuit and to connect said necessary optical elements to said semiconductor integrated circuit;
covering said necessary optical elements that have been connected to said semiconductor integrated circuit with a protective film;
removing unnecessary optical elements that are not covered with said protective film from said optical element array; and
removing said protective film; and
a second optical element mounting step that includes steps of:
covering necessary optical elements in an optical element array with a protective film;
removing the functional portions of unnecessary optical elements that are not covered by said protective film;
removing said protective film; and
mounting said optical element array in which the functional portions of said unnecessary optical elements have been removed to said semiconductor integrated circuit, and connecting said necessary optical elements to said semiconductor integrated circuit.

20. A fabrication method of an optical-element integrated semiconductor integrated circuit according to claim 19, wherein light-emitting devices are mounted on said semiconductor integrated circuit by one of said first and second optical element mounting steps, and photodetectors are mounted on said semiconductor integrated circuit by the other optical element mounting step.

21. A fabrication method of an optical-element integrated semiconductor integrated circuit according to claim 17, said method including a step of etching said element substrate to produce a thin film.

22. A fabrication method of an optical-element integrated semiconductor integrated circuit according to claim 18, said method including a step of etching said element substrate to produce a thin film.

23. A fabrication method of an optical-element integrated semiconductor integrated circuit according to claim 19, said method including a step of etching said element substrate to produce a thin film.

24. A fabrication method of an optical-element integrated semiconductor integrated circuit according to claim 17, said method including a step of etching said element substrate to form a lens.

25. A fabrication method of an optical-element integrated semiconductor integrated circuit according to claim 18, said method including a step of etching said element substrate to form a lens.

26. A fabrication method of an optical-element integrated semiconductor integrated circuit according to claim 19, said method including a step of etching said element substrate to form a lens.
